(19) United States
(12) Patent Application Publication
(10) Pub. No.: US 2008/0050058 A1
(43) Pub. Date: Feb. 28, 2008

(54) Method and Device for Monitoring a Temperature of a Bearing of a Rotating Shaft

(76) Inventor: KARL-HEINZ FILBRY, Hochheim (DE)

Correspondence Address: HENRY M FEIEREISEN, LLC, 350 FIFTH AVENUE, SUITE 4714, NEW YORK, NY, 10118, US

(21) Appl. No.: 11/577,551

(22) PCT Filed: Oct. 18, 2005
(86) PCT No.: PCT/EP05/55324

§ 371 Date: Apr. 19, 2007

(30) Foreign Application Priority Data
Oct. 19, 2004 (DE) 10 2004 050 898.4

(51) Int. Cl. H02K 5/16; H02K 11/00; F16C 41/04; G01P 3/48; G01R 33/025; H02K 7/08; G01P 3/54

(52) U.S. Cl. 384/448; 310/90; 310/68 C; 324/174; 324/207.12

(57) ABSTRACT

The invention relates to a method and a device for monitoring the temperature of a bearing (1b) of a rotating shaft (2). According to the invention, a resolver (3) is placed in the vicinity of the bearing (1b) and a measuring current (Iₘₑₛₛ) is applied to the stator winding (4) of said resolver (3). A total ohmic resistance (RG), composed of the ohmic resistance of the stator winding (4) and the ohmic resistance (R_{L}) of the electric supply lines (13) to the stator winding (4), is determined by means of the measuring current (Iₘₑₛₛ) and by means of an electric voltage drop (Uₘₑₛₛ) that is caused by the measuring current (Iₘₑₛₛ) through the stator winding (4) and the supply lines (13). If the total ohmic resistance (R_{G}) and/or the temperature (T) of the resolver (3) that has been determined from the total ohmic resistance (R_{G}) exceeds a threshold value, an excess temperature of the bearing (1b) is identified. The invention provides a method and a device for monitoring the temperature of a bearing (1b) of a rotating shaft (2), which do not require a temperature sensor to monitor the temperature.

The invention relates to a method and a device for monitoring a temperature of a bearing of a rotating shaft.

There is frequently the need in motors, in particular in electric motors, to monitor the temperature of the bearings of a rotating motor shaft of the motor in order to avoid damage to the bearings and damage to the motor shaft.

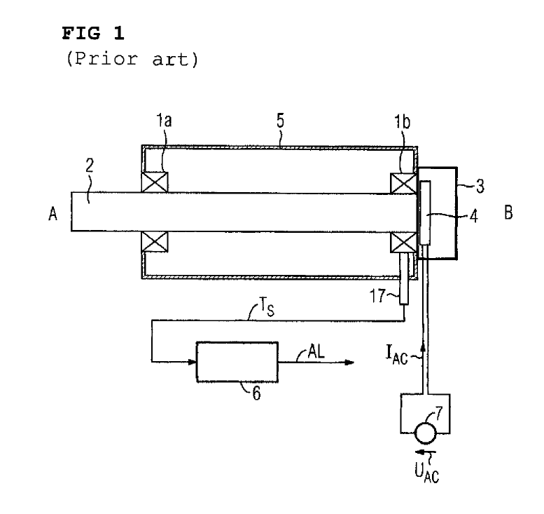

FIG. 1 is a schematic of the commercial method for monitoring a temperature of a bearing of a rotating motor shaft. The motor illustrated by way of example in FIG. 1 comprises two bearings 1a and 1b for bearing a rotating motor shaft 2, and a housing 5. The motor has two ends that are denoted in FIG. 1 by A and B. Of course, the motor comprises yet further elements, which are, however, not illustrated in FIG. 1, because they are not essential for understanding the invention.

The motor further has an inductively operating position sensor, in the form of a resolver 3, for measuring a position, that is to say an angular position of the motor shaft with reference to a zero point and/or for measuring the rotational speed. Apart from other components that are, however, not illustrated for the sake of clarity and because they are not essential for understanding the invention, the resolver 3 has a stator winding 4. The stator winding 4 of the resolver 3 is connected to an AC voltage source U_{AC}. The AC voltage source U_{AC} generates in the stator winding 4 of the resolver 3 an alternating current I_{AC} that produces in a rotor winding (not illustrated) of the rotor of the resolver a signal that is modulated by the rotary movement of the rotor. The position of the motor shaft 2 is determined with the aid of the signal modulated in such a way.

In order to measure the temperature of the dead end bearing 1b, there is fitted on the bearing 1b a temperature sensor 17 that relays the temperature T_{S} of the bearing 1b to an external evaluation unit 6. The evaluation unit 6 essentially comprises a limit monitor that outputs an alarm signal AL when the maximum permissible bearing temperature is exceeded. Since it generally possible to infer the temperature of the drive end bearing 1a from the temperature T_{S} of the dead end bearing 1b, in many cases no separate monitoring of the temperature of the drive end bearing 1a is carried out.

This commercially used monitoring of the bearing temperature has a few disadvantages. Thus, on the one hand it is necessary to provide a temperature sensor 17, and on the other hand it is commercial practice to connect an external evaluation unit 6 to the temperature sensor 5 so as to implement the temperature monitoring. The external evaluation unit 6 is a separate apparatus here, and not a component of a control or regulation device present in any case for controlling and/or regulating the motor. The said disadvantages render the abovedescribed method, carried out commercially, for monitoring the temperature of the motor bearing expensive and complicated.

It is the object of the invention to specify a method and a device for monitoring a temperature of a bearing of a rotating shaft in the case of which no temperature sensor is required to monitor the temperature.

This object is achieved by means of a method for monitoring a temperature of a bearing of a rotating shaft,
in which a resolver is arranged in the vicinity of the bearing,
in which a measuring current is applied to a stator winding of the resolver,
in which a total ohmic resistance consisting of the ohmic resistance of the stator winding and ohmic resistance of the electric supply leads to the stator winding is determined by means of the measuring current and by means of an electric voltage drop occurring owing to the measuring current via the stator winding and the supply leads,
in which an excess temperature of the bearing is identified if the total ohmic resistance and/or the temperature of the resolver ascertained from the total ohmic resistance exceeds a limiting value.

Furthermore, this object is achieved by means of a device for monitoring a temperature of a bearing of a rotating shaft, a resolver being arranged in the vicinity of the bearing, in which the device has,
means for applying a measuring current to a stator winding of the resolver,
means for determining a total ohmic resistance that consists of an ohmic resistance of the stator winding and an ohmic resistance of the electric supply leads to the stator winding, the measuring current and an electric voltage drop occurring owing to the measuring current being evaluated via the stator winding and the supply leads,
means for monitoring the total ohmic resistance for the exceeding of a limiting value, an excess temperature of the bearing being identified when the limiting value is exceeded, and/or
means for monitoring a temperature of the resolver ascertained from the total ohmic resistance for the exceeding of a limiting value, an excess temperature of the bearing being identified when the limiting value is exceeded.

A first advantageous design of the invention is characterized in that the measuring current has a DC component, the total ohmic resistance being determined by means of the DC component and by means of an electric voltage drop occurring owing to the DC component via the stator winding and the supply leads. The total ohmic resistance can be determined in a particularly simple fashion owing to the use of the DC component of the measuring current.

It emerges, moreover, as being advantageous when the temperature T of the resolver is ascertained from the total ohmic resistance by using the relationship

$$T = \frac{( {R}_{G} - {R}_{20} - {R}_{L} )}{{R}_{20} \cdot α} + 20 ° C .$$

R_{G} being the total ohmic resistance consisting of the ohmic resistance of the stator winding and ohmic resistance of the electric supply leads to the stator winding during operation, R_{L} being the resistance of the electric supply leads, and R₂₀ being the resistance of the stator winding of the resolver at 20° C., and α being the temperature coefficient referring to 20° C. As a result, the temperature T of the resolver can be ascertained particularly accurately.

It furthermore emerges as being advantageous when the limiting value is selected such that it corresponds to the maximum permissible temperature of the bearing minus the temperature gradient between the temperature of the resolver and the temperature of the bearing. The temperature gradient between resolver and bearing is also thereby taken into account.

It furthermore emerges as being advantageous when the shaft is constructed as the motor shaft of a motor. Specifically in the case of motor shafts, it is frequently necessary to monitor the temperature of the bearings of the motor shaft.

It furthermore emerges as being advantageous when the device according to the invention is designed as a control and/or regulation device for controlling and/or regulating a motor.

Furthermore, it emerges as advantageous when a computer program product for the inventive device is provided that includes code sections with the aid of which the inventive method can be executed.

Advantageous designs of the device follow by analogy with the advantageous designs of the method, and vice versa.

An exemplary embodiment of the invention is illustrated in the drawing and will be explained in more detail below. In the drawing:

FIG. 1 shows a temperature monitoring of a bearing according to the prior art, and

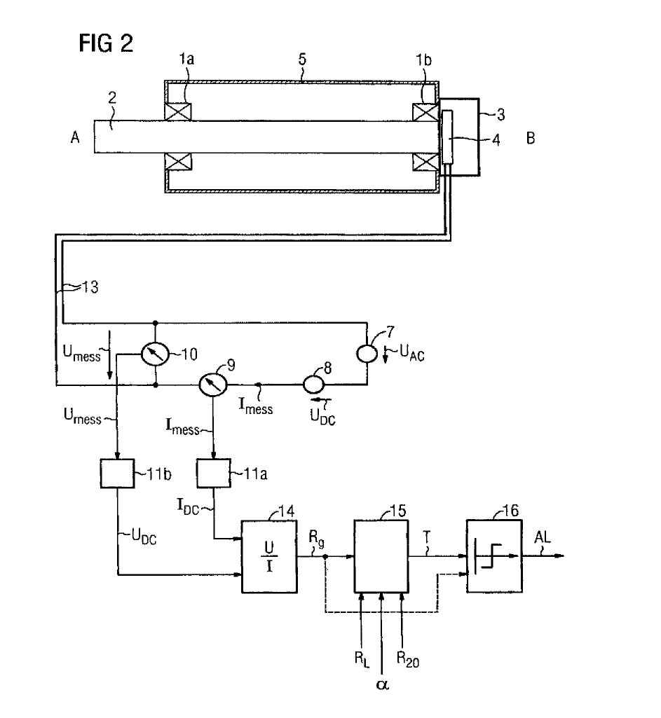

FIG. 2 shows an inventive device and method for monitoring a temperature of a bearing of a rotating shaft by example of a motor shaft of a motor.

FIG. 2 illustrates the inventive method and the inventive device in the form of an exemplary embodiment. The motor illustrated in FIG. 2 corresponds essentially in basic design to the motor previously described in FIG. 1. Identical elements are therefore provided in FIG. 2 with identical reference symbols to those in FIG. 1. The sole substantial difference with reference to the motor consists in that the motor in accordance with FIG. 2 has no temperature sensor 7 in accordance with FIG. 1. Of course, the motor comprises yet further elements, which are, however, not illustrated in FIG. 2, because they are not essential for understanding the invention.

According to the invention, the heating of the stator winding 4 of the resolver 3 is utilized to monitor the temperature of the bearing 1b of the motor shaft. The resolver 3 for measuring the position and/or the rotational velocity of the motor shaft is usually preferably arranged in motors in the immediate vicinity of one of the two bearings of the motor shaft 2 such that the temperature of the bearing is transferred to the temperature T of the resolver 3 and thus to the stator winding 4 of the resolver 3. In the exemplary embodiment, the resolver 3 is fastened on the dead end of the motor directly at the end shield of the dead end bearing 1b such that a good heat transfer is ensured between the bearing 1b and the resolver 3.

Because of the arrangement of the resolver 3 in the immediate vicinity of the bearing 1b, the temperature gradient between bearing 1b and resolver 3 is slight. As already mentioned above, as an integral component the resolver 3 has a stator winding 4 that is heated by the bearing 1b to the same extent as the overall resolver 3. The heating of the stator winding 4 increases its ohmic resistance, and this is used according to the invention to monitor the temperature of the bearing.

In order to determine a total ohmic resistance R_{G} that is additively composed of the ohmic resistance of the stator winding R_{S} and the ohmic resistance R_{L} of the supply leads 13 to the stator winding 4, that is to say the total ohmic resistance R_{G} consists of the ohmic resistance R_{S} of the stator winding and the ohmic resistance R_{L} of the supply leads to the stator winding, a voltmeter 10 is used to measure a voltage drop Uₘₑₛₛ that drops over the supply leads 13 (the supply leads are drawn somewhat more thickly in FIG. 2) and the stator winding 4, and an ammeter 9 is used to measure the measuring current Iₘₑₛₛ that flows through the stator winding 4 and the supply leads 13. The measuring current Iₘₑₛₛ that is applied to the stator winding 4 of the resolver is generated on the one hand, by the AC voltage source 7 required for directly operating the resolver 3 and which generates the AC voltage U_{AC}, and on the other hand by an additional DC voltage source 8 that generates a DC voltage U_{DC}. The measuring current Iₘₑₛₛ is thus composed additively of a DC component I_{DC} generated by the DC voltage source 8, and of an AC component I_{AC} generated by the AC voltage source 7.

The total ohmic resistance R_{G} is ascertained below with the aid of the DC component I_{DC}, generated by the voltage source 8, of the measuring current Iₘₑₛₛ, and of the voltage drop Uₘₑₛₛ occurring as a consequence of the measuring current Iₘₑₛₛ via the stator winding 4 and the supply leads 13 to the stator winding 4. To this end, the voltage drop Uₘₑₛₛ is fed to a filter 11b as input variable, and the current Iₘₑₛₛ is fed to a filter 11a as input variable. The filter 11b filters the DC voltage component U_{DC} out of the voltage Uₘₑₛₛ, and the filter 11a filters the DC component I_{DC} generated by the DC voltage source 8 out of the measuring current Iₘₑₛₛ. The filters 11a and 11b can be present to this end in the form, for example, of lowpass filters that filter out the respective alternating components.

The DC component I_{DC} and the DC voltage component U_{DC} are subsequently fed as input variable to a resistance ascertaining unit 14 that ascertains the total ohmic resistance R_{G} as output variable by dividing the DC voltage component U_{DC} by the DC component I_{DC}.

The total resistance R_{G} is fed as input variable to a temperature ascertaining unit 15 that ascertains the temperature of the stator winding and thus, to a good approximation, the temperature T of the resolver. The temperature ascertaining unit 15 in this case preferably ascertains the temperature T of the resolver from the total ohmic resistance R_{G} by using the relationship

$$T = \frac{( {R}_{G} - {R}_{20} - {R}_{L} )}{{R}_{20} \cdot α} + 20 ° C . \qquad ( 1 )$$

R_{G} being the total ohmic resistance consisting of the ohmic resistance of the stator winding and ohmic resistance of the electric supply leads to the stator winding during operation of the motor, R_{L} being the resistance of the electric supply leads, and R₂₀ being the resistance of the stator winding of the resolver at 20° C., and α being the temperature coefficient referring to 20° C.

The resistance R_{L} of the electric supply leads 13 can in this case be ascertained in advance by measurement when commissioning the motor, or by calculation from the cross section of the supply leads 13, from the material of the supply leads 13, and the length of the supply leads 13 by means of the relationship

$${R}_{L} = \frac{l}{χ * A} , \qquad ( 2 )$$

in which
l: length of the supply leads (total length of outgoing and return lead)
A: cross section of the supply leads, and
χ=specific conductivity of the material of the supply leads. The resistance R₂₀ of the stator winding of the resolver at a nominal temperature of 20° C. can be measured by measuring the resolver in the idle state at an ambient temperature of 20° C. However, the resistance R₂₀ of the stator winding of the resolver is frequently also specified directly by the manufacturer of the resolver.

The temperature coefficient α is calculated in generally known physical tables and is, for example, 1/255 1/Kelvin for copper.

The temperature T of the resolver ascertained in such a fashion is fed as input variable to a limit monitor 16. When the temperature T of the resolver that is ascertained from the total ohmic resistance R_{G} exceeds a limiting value, an excess temperature of the bearing is identified and the limit monitor 16 produces an alarm signal AL. The limiting value is preferably selected in this case such that it corresponds to the maximum permissible temperature of the bearing minus the temperature gradient occurring between the temperature of the resolver and the temperature of the bearing. If the limiting value is selected in such a way as described above, account is also taken of the usually slight temperature gradient occurring between the temperature of the bearing and the temperature of the resolver, and the monitoring of the temperature of the bearing becomes very accurate.

However, it is also conceivable, alternatively, not to determine the temperature T of the resolver from the total ohmic resistance R_{G}, but to feed the total ohmic resistance R_{G} directly to the limit monitor 16 as input variable, as indicated in the dashed fashion drawn in FIG. 1. If the total ohmic resistance R_{G} exceeds a limiting value, this is identified as an excess temperature of the bearing, and the limit monitor 16 produces an alarm signal AL.

However, it is also conceivable to design the limit monitor 16 such that both the total ohmic resistance R_{G} and the temperature T of the resolver are simultaneously monitored for the exceeding of a respectively associated limiting value, and that an excess temperature of the bearing is identified in such a way and an alarm signal AL is produced.

Furthermore, it is also, of course, conceivable not to provide a DC voltage source 8, but to use only the AC voltage source 7 present in any case for the functioning of the resolver in order to carry out the inventive method. The determination of the total ohmic resistance R_{G} is then performed by determining the real part of the total impedance Z_{G} that is composed additively of the impedance of the stator winding and the impedance of the supply leads, the total impedance Z_{G} being determined from the measuring voltage Uₘₑₛₛ and the measuring current Iₘₑₛₛ, which in this case do not include any direct component, but exclusively only an alternating component. The determination of the total impedance Z_{G} and of its real part is performed in the resistance ascertaining unit 14. The two filters 11a and 11b are eliminated in this design of the invention.

It is particularly advantageous when the inventive device is designed as a control and/or regulation device for controlling and/or regulating the motor, since such a control and/or regulation device is present in any case for regulating and/or controlling the motor. An additional external evaluation unit 6 in accordance with FIG. 1 for monitoring the bearing temperature in accordance with the prior art can thereby be eliminated.

Furthermore, it is advantageous to provide a computer program product, for example in the form of a diskette, a hard disk, a compact disk, a flash card or in the form of another storage medium that includes code sections with aid of which the inventive method can be executed on the inventive device.

It may further be pointed out that the DC voltage source 8 can also be present in the form of a regulated DC voltage source, and as such be operated as a DC source that generates a constant DC component I_{DC}.

Since it is generally also possible to infer the temperature of the drive end bearing 1a from the temperature of the dead end bearing 1b, the inventive method and the inventive device generally also simultaneously monitor the drive end bearing 1a.

Furthermore, it may be expressly noted at this juncture that the inventive method and the inventive device are, of course, suitable not only for monitoring a temperature of a bearing of a rotating motor shaft of a motor, but also in an entirely general fashion for monitoring a temperature of a bearing in the case of other rotating shafts such as, for example, shafts of generators.

It may further be noted at this juncture that the bearings 1a and 1b can be designed as rolling-contact bearings, for example.

1. A method for monitoring a temperature of a bearing of a rotating shaft, comprising the steps of:
arranging a resolver proximate to the bearing,
applying via supply leads a measuring current to a stator winding of the resolver,
measuring the measuring current and an electric voltage drop across the stator winding and the supply leads caused by the measuring current,
determining from the electric voltage drop and the measuring current a total ohmic resistance of the stator winding and the supply leads, and
identifying an excess temperature of the bearing if the total ohmic resistance or a temperature of the resolver derived from the total ohmic resistance, or both, exceed a limit value.

2. The method as claimed in claim 1, wherein the measuring current has a DC component, and wherein the total ohmic resistance is determined from the electric voltage drop across the stator winding and the supply leads caused by the DC component.

3. The method as claimed in claim 1, wherein the temperature T of the resolver is derived by using the relationship
$$T = \frac{( {R}_{G} - {R}_{20} - {R}_{L} )}{{R}_{20} \cdot α} + 20 ° C .$$
wherein R_{G} is the total ohmic resistance, R_{L} is the resistance of the electric supply leads, R₂₀ is the resistance of the stator winding of the resolver at a temperature of 20° C., and α is a temperature coefficient of the electrical resistance of the stator winding at a temperature of 20° C.

4. The method as claimed in claim 1, wherein the limit value is selected so as to correspond to a maximum permissible temperature of the bearing minus a temperature gradient between the temperature of the resolver and the temperature of the bearing.

5. The method as claimed claim 1, wherein the rotating shaft is constructed as a motor shaft of a motor.

6. A device for monitoring a temperature of a bearing of a rotating shaft, comprising:
a resolver arranged proximate to the bearing, said resolver having a stator winding and electric leads connected to the stator winding,
means for applying a measuring current to the stator winding,
means for measuring the measuring current and an electric voltage drop across the stator winding and the supply leads caused by the measuring current, and for determining from the electric voltage drop and the measuring current a total ohmic resistance of the stator winding and the supply leads, and
means for identifying an excess temperature of the bearing if the total ohmic resistance or
a temperature of the resolver derived from the total ohmic resistance, or both, exceed a limit value.

7. The device as claimed in claim 6, wherein the device is implemented as a controller for controlling or regulating a motor.

8. A computer program product embodied on a computer-readable medium, said computer program including computer code which, when executed on a computer, enables the computer to perform the method as claimed in claim 1.

9. A device for monitoring a temperature of a bearing of a rotating shaft, comprising:
a resolver arranged proximate the bearing, said resolver having a stator winding and electric leads connected to the stator winding,
a current supply for applying a measuring current to the stator winding,
a current meter for measuring the measuring current and a voltage meter for measuring an electric voltage drop across the stator winding and the supply leads caused by the measuring current,
a filter unit for filtering from the measuring current and the electric voltage drop respective DC current and voltage components, wherein a total ohmic resistance of the stator winding and the supply leads is determined from the DC current and voltage components, and
a temperature determination unit for identifying an excess temperature of the bearing if the total ohmic resistance or a temperature of the resolver derived from the total ohmic resistance, or both, exceed a limit value.
